(19) United States
(12) Patent Application Publication
(10) Pub. No.: US 2005/0236693 A1
(43) Pub. Date: Oct. 27, 2005

(54) Wafer stabilization device and associated production method

(76) Inventors: Werner Kroninger, Albersdorf (DE); Josef Schwaiger, Teugn (DE)

Correspondence Address: BRINKS HOFER GILSON & LIONE;INFINEON, PO BOX 10395, CHICAGO, IL, 60610, US

(21) Appl. No.: 11/106,666

(22) Filed: Apr. 13, 2005

(30) Foreign Application Priority Data
Apr. 15, 2004 (DE) 10 2004 018 250.7

(51) Int. Cl. H01L 29/06; H01L 21/46

(52) U.S. Cl. 257/619; 438/455; 438/457; 438/459

(57) ABSTRACT

A stabilization device and method for stabilizing a workpiece such as a thin film wafer is presented. The thin wafer is fixed and oriented in planar fashion. The stabilization device is realized by a profiled ring which is arranged on the periphery of the wafer and is intimately connected thereto. The stabilization device and wafer are connected via negative pressure or by means of an adhesive having high thermal stability. The wafer and device are formed from similar semiconductor materials and have the same outline contour. The stabilization device remains on the wafer during process steps in the course of production and processing of the wafer.

### PRIORITY

This application claims the benefit of priority to German Patent Application 10 2004 018 250.7, filed on Apr. 15, 2004, herein incorporated by reference in its entirety.

### TECHNICAL FIELD

The invention relates to a device for stabilizing a workpiece, in particular a thin wafer, which is fixed and oriented in planar fashion, and to a method for producing this device.

### BACKGROUND

Semiconductor materials in the form of wafers are used for producing electronic components. Integrated circuits are produced on such a disk in processing stations and production lines. For this purpose, a wafer is transported step by step from one production unit to the next. The identification, fixing and relative orientation of the wafer with respect to each processing unit are significant in this case.

Wafers having a larger diameter are increasingly being used in the course of technical developments; diameters of 5 to 6 inches can be produced as standard and diameters of 8 inches have already been realized. Moreover, attempts are being made to further reduce the material thickness of these wafers. These wafers exhibit warping of up to 10 mm given a diameter of 5 inches in relation to a planar orientation of the wafer. Furthermore, as the mechanical instability increases, the more thinly the wafer is produced. In the process steps provided for the wafer, deformations and instabilities of this type mean that it is difficult, if not impossible to work with automatic handling systems at present as in many cases, such an unstable and warped wafer cannot be processed in a standardized unit.

The problem of instability and distortion has occurred to an increased extent with the use of extremely thin wafers. These thin wafers are almost without exception deformed or deform continually in the course of handling. A further decrease in the layer thickness of wafers in the future may give rise to even greater problems. This wafer instability has the effect that previous handling systems for thin wafers fail and the rejects in the course of production are comparatively high.

### BRIEF SUMMARY

By way of introduction only, a device and a method for producing a device in which thin waters can be handled more simply and more securely are presented. The mechanically unstable and/or deformed thin wafers are able to be stabilized, fixed and, if appropriate, oriented uniformly.

In one embodiment, unstable and distorted thin wafers can be processed and handled securely in terms of production in processing processes and also, upstream and downstream, on transport paths. A stabilization device in the form of a carrier system which fixedly holds the thin wafer and orients it in planar fashion is used. The function of such a carrier system is ensured by a stiff profile, which is arranged at the peripheral region of the thin wafer on at least one of its parallel surfaces and is intimately connected thereto. In order to eliminate deformation of the thin wafer, the thin wafer is shaped by the external force applied by means of the device such that thin wafer assumes a planar shape and also retains the planar shape during the subsequent processes.

The production of a stabilization device in the form of a carrier ring may be realized with the aid of negative pressure. Using a device with an annular configuration, the thin wafer and the device have bearing areas on the end side which lie in a common plane and axes connected to negative pressure chambers. The negative pressure chambers are evacuated via a valve after the emplacement of a thin wafer. Adhesive may be applied to the bearing area in order to support the connection.

In order to apply a holding force, an electrostatic force may also be applied to the wafer. In this case, the wafer is held on the carrier by the electrostatic force. This is done by using dielectrics which are distributed over a carrier or over a carrier ring in a similar manner to intake nozzles. As soon as the wafer has been emplaced and fixed, electrical supply lines are removed. As a result of the corresponding insulation, the existing polarization preserves the electrostatic holding force for a sufficient time even without a voltage supply.

The basic body of a carrier described is produced from material having an expansion coefficient that is identical or similar to that of the wafer. This ensures that it is intrinsically stable given a sufficient thickness, can sufficiently support the wafer, can be used even in aggressive environments, and stresses between the carrier and the wafer do not occur or are minimized in the event of temperature fluctuations.

The foregoing summary has been provided only by way of introduction. Nothing in this section should be taken as a limitation on the following claims, which define the scope of the invention.

### BRIEF DESCRIPTION OF THE DRAWINGS

The invention will be explained in more detail in the following text using a number of exemplary embodiments and with reference to the drawings, in which:

FIG. 1 shows a cross section through a finished composite of carrier ring with wafer;

FIG. 2 shows a plan view of a composite in accordance with FIG. 1;

FIG. 3 shows a side view of the thin wafer;

FIG. 4 shows a side view of the unprocessed carrier wafer;

FIG. 5 shows a side view of the unprocessed composite of the carrier wafer and thin wafer; and

FIG. 6 shows a completed composite in accordance with FIG. 1.

In the figures, identical or functionally identical elements are provided with the same reference symbols.

### DETAILED DESCRIPTION OF THE PREFERRED EMBODIMENTS

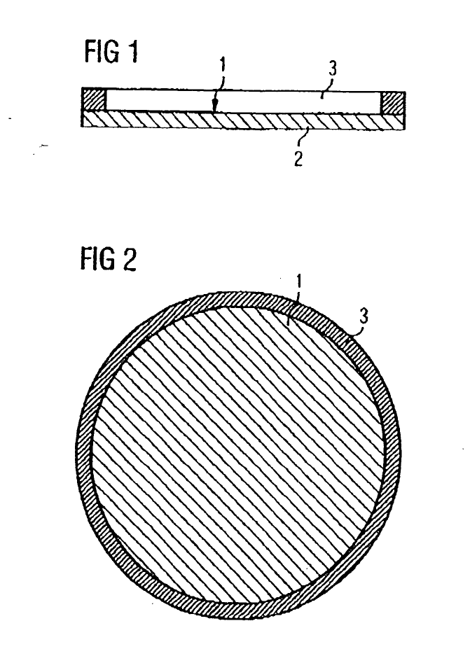

A composite 1 is illustrated in FIG. 1. The composite 1 comprises a thin wafer 2 and a stabilization device in the form of a carrier ring 3. The thin wafer 2 and carrier ring 3 are intimately connected to one another such that the thin wafer 2 bears on the carrier ring 3 in a planar and dimensionally stable manner and can be handled and also processed.

The geometry of the carrier ring 3 for the thin wafer 2 may be designed in different ways. For example, if the processing of the thin wafer 2 takes place on both sides, the stabilization device is designed as a simple carrier ring 3 and receives a thin wafer 2, bearing areas in the form of an annulus being present only on the peripheral region of the wafer 2. This is illustrated in plan view in FIG. 2.

This structure precludes neither front-side nor rear side processing of the thin wafer 2, so that the thin wafer 2 can be processed on both sides. The carrier ring 3 is designed such that the bearing areas of the carrier ring 3 support the thin wafer 2 at the locations at which no processing takes place. This is generally the outer edge region of a circular thin wafer 2. Consequently, in the course of processing, an annular carrier 3 affords access to the entire front side and access to the largest region of the rear side of the thin wafer 2. The carrier ring 3 or the carrier area may also have interruptions as required, so that segments of the carrier ring are uniformly distributed over the periphery, as a result of which, however, the stability decreases correspondingly.

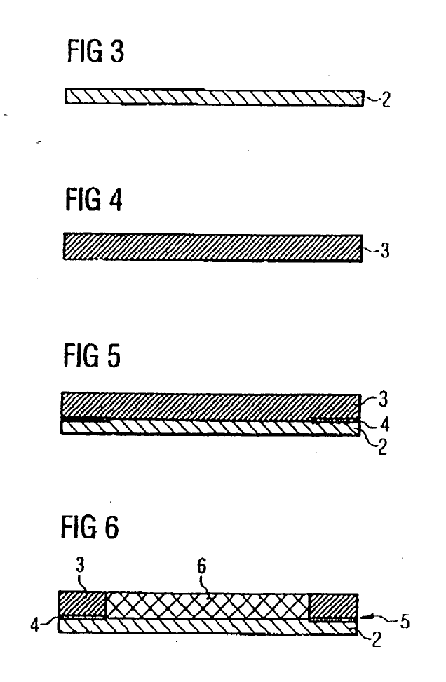

The wafer 2 may be a semiconductor substrate made of a semiconductor material, e.g. silicon. Such a semiconductor substrate is also referred to as a device wafer 2 and has the form of a disk, which is illustrated in side view in FIG. 3. The carrier ring 3 is, for example likewise a semiconductor substrate or is produced from some other suitable material and is also referred to as a carrier wafer. The original form of the carrier ring 3 may likewise be that of a disk, as illustrated in FIG. 4.

One of the processing operations described previously may be for example thinning the wafer 2 by grinding. A fixing means serves for fixing the wafer 2 to the stabilization device designed as a carrier wafer 3. The fixing means may be arranged between the wafer 2 and the carrier wafer 3 to enable unimpeded processing of the wafer 2 and to ensure a connection even for wafers 2 at the risk of fracture. Such a fixing means may be adhesive 4, which in accordance with the illustration in FIG. 5, is situated at least in partial regions 5 between the wafer 2 and the carrier wafer 3.

In one configuration in accordance with FIGS. 3 to 5, a semiconductor wafer is used as a carrier for a workpiece, which is also a semiconductor wafer. This avoids the use of a dummy wafer or a test wafer. The thickness of the workpiece carrier wafer is arbitrary.

In a further configuration which works with vacuum between wafer 2 and carrier wafer 3, there is practically no gap between wafer 2 and carrier wafer 3. If both wafers comprise silicon, for example, then the coefficients of thermal expansion are identical. In addition, it is possible to use carrier wafers which are a byproduct of semiconductor fabrication. The use of such carrier wafers thus does not increase the overall cost.

In one configuration, the wafer 2 is connected to the carrier wafer 3 by means of a ring of a high-temperature resistant substance, for example by means of a 360° adhesive bond. By way of example, an adhesive which comprises palladium is suitable as a connecting means. The annular connection location that arises in this case may be situated at the edge of the wafers, for example. Outside the active chip area, release of the connection prior to the completion of the wafer 2 may not be desirable because the carrier wafer 3 is intended to stabilize the thin wafer 2.

As a result of the stabilizing connection of thin wafer 2 and carrier wafer 3, the thin wafer 2 can be processed further by means of commercially available installations, e.g. by means of an ion implanter, a CVD (chemical vapor deposition) installation, a sputtering installation, an exposure installation, in a lithography process or in a furnace process or in a thermal irradiation process, e.g. in an RTP (rapid thermal annealing) process. The increased thickness of the composite comprising thin wafer 2 and carrier wafer 3 mitigates possible handling problems.

In another embodiment, wafer 2 and carrier wafer 3 have the same outlines. By virtue of this, it is possible to use processing installations for specific workpiece thicknesses even when the wafers 2 are particularly thin. Conversions are not necessary because the thickness and the outline of the composite 1 comprising wafer 2 and carrier wafer 3 correspond to the thickness and the outline of an unthinned workpiece.

In another embodiment, wafer 2 and carrier wafer 3 are round disks, in particular semiconductor wafers, if appropriate with a so called flat or a notch for identifications of a crystal direction. If carrier wafer 3 and thin wafer 2 comprise the same material or the same material composition, then it is possible to carry out thermal processes without additional stresses on account of the connection or on account of the composite with the carrier wafer 3. Since the wafer 2 usually comprises a semiconductor material, the processing may involve carrying out a method for processing semiconductor material such as a lithography method, a metallization method, a layer application method, a layer patterning method, an implantation method, a furnace process or a thermal irradiation process.

The methods for processing (for example thinning by grinding) the wafer 2 may be carried out on the rear side of the wafer 2, i.e. on a side that contains no active components, such as e.g. transistors.

In one of the possible production methods for producing a carrier wafer 3, the contour of the carrier ring 3 is worked out by sawing, milling, grinding or a laser processing. The processed, crosshatched region 6 in FIG. 6 is then obviated and only the carrier ring 3 is retained. These methods are suitable for workpieces or workpiece carriers made of glass, ceramic or semiconductor materials. Hole circular saw blades for producing the contour of the carrier wafer 3 are also conceivable. Chemical methods, for example etching methods, are also suitable for producing the profile contour of the carrier wafer 3. At least one fixing means is arranged between the workpiece and the workpiece carrier. If the fixing means is an adhesive, the adhesive is thermostable for temperatures of up to 200° C. or up to 400° C. or up to 800° C. or even up to 1200° C. The processing of the workpiece involves carrying out a high temperature process in which the temperature in order for the abovementioned temperatures is for example greater than 150° C., greater than 350° C., greater than 700° C. or greater than 1000° C. However, the production of the contour of the carrier wafer 3 is carried out at a temperature that lies below the processing temperature.

To summarize, the present invention is suitable for applying semiconductor wafers on carrier wafers and for stabilizing the semiconductor wafers such that the wafers can be processed better. The processes include grinding, sputtering, wet chemistry (SEZ etch; Marangoni dryer; etc.), spin etch, cleaning, implantation, PVD and others. The technical terms which are used by experts predominantly only as English language terms have been used in the above description.

It is therefore intended that the foregoing detailed description be regarded as illustrative rather than limiting, and that it be understood that it is the following claims, including all equivalents, that are intended to define the spirit and scope of this invention. Nor is anything in the foregoing description intended to disavow scope of the invention as claimed or any equivalents thereof.

1. A stabilization device for stabilizing thin disks having parallel surfaces, the device comprising a material forming a stiff profile arranged at and intimately connected to a peripheral region of a thin disk on a parallel surface of the thin disk.

2. The device as claimed in claim 1, wherein the device is formed by a ring.

3. The device as claimed in claim 1, wherein the device comprises the same material or a material having the same physical properties as the thin disk.

4. The device as claimed in claim 3, wherein the device comprises semiconductor material.

5. The device as claimed in claim 4, wherein the device is formed from a semiconductor wafer.

6. The device as claimed in claim 1, wherein the device and the thin disk have the same outline contour.

7. The device as claimed in claim 1, wherein the device remains on the thin disk during process steps in the course of production and processing of the thin disk.

8. A method for producing a stabilization device comprising a material forming a stiff profile arranged at and intimately connected to a peripheral region of a thin disk having parallel surfaces on a parallel surface of the thin disk, the method comprising connecting the thin disk and the stabilization device to one another.

9. The method as claimed in claim 8, wherein the thin disk and the stabilization device are connected to one another using at least one of an adhesive-bonding connection, a press-on operation or complete vulcanization.

10. The method as claimed in claim 9, wherein the press-on operation is supported by creating negative pressure between the thin disk and the stabilization device.

11. The method as claimed in claim 9, wherein the adhesive-bonding connection is produced by means of an adhesive having high thermal stability.

12. The method as claimed in claim 8, wherein the thin disk and the stabilization device are connected parallel to one another.

13. The method as claimed in claim 8, wherein a profile contour of the stabilization device is produced by at least one of mechanical or chemical processing from a carrier material thereof.
